(19) United States
(12) Patent Application Publication
(10) Pub. No.: US 2014/0246725 A1
(43) Pub. Date: Sep. 4, 2014

(54) Integrated Circuit Memory Devices Including Parallel Patterns in Adjacent Regions

(71) Applicant: Samsung Electronics Co., Ltd., Gyeonggi-do (KR)

(72) Inventors: Seungseob Lee, Suwon-si (KR); Hyuckjoon Kwon, Yongin-si (KR)

(73) Assignee: Samsung Electronics Co., Ltd., Gyeonggi-do (KR)

(21) Appl. No.: 14/196,512

(22) Filed: Mar. 4, 2014

Related U.S. Application Data
(60) Provisional application No. 61/772,174, filed on Mar. 4, 2013.

(30) Foreign Application Priority Data
Aug. 19, 2013 (KR) 10-2013-0098089

(51) Int. Cl. H01L 27/108

(52) U.S. Cl. CPC H01L 27/10897
USPC 257/368

(57) ABSTRACT

An integrated circuit memory device includes a substrate having a sense amplifier region or a word line driver region comprising circuits configured to operate a memory cell array. The substrate further includes a conjunction region adjacent the sense amplifier region or word line driver region and defining a boundary therebetween. A plurality of gate patterns extends on the substrate. The gate patterns include peripheral gate patterns extending in the sense amplifier region or word line driver region, and conjunction gate patterns extending in the conjunction region. Ones of the conjunction gate patterns and ones of the peripheral gate patterns proximate the boundary extend substantially parallel along the boundary between the conjunction region and the sense amplifier region or word line driver region.

### CROSS-REFERENCE TO RELATED APPLICATIONS

This U.S. non-provisional patent application claims priority under 35 U.S.C. §119 to U.S. Provisional Patent Application No. 61/772,174, which was filed on Mar. 4, 2013 in the United States Patent and Trademark Office, and Korean Patent Application No. 10-2013-0098089, which was filed on Aug. 19, 2013 in the Korean Intellectual Property Office, the entire contents of which are hereby incorporated by reference herein.

### BACKGROUND OF THE INVENTION

Example embodiments of the inventive concept relate to semiconductor memory devices.

A dynamic random access memory (DRAM) device is a type of semiconductor memory device that typically includes a plurality of cell array regions arranged in rows and columns, a sub-word line driver region, a bit line sense amp region, and a conjunction region. In such a DRAM device, a sense amplifier may be configured to sense and amplify data stored in the memory cell (MC) and then transmit the data to an external device. However, as an integration density of the semiconductor device increases, an allowed area for each of such regions may become smaller.

### SUMMARY

Example embodiments of the inventive concept can provide a semiconductor memory device capable of reducing a discrepancy in line width of gate patterns provided in the sense amp region.

According to some example embodiments of the inventive concept, an integrated circuit memory device includes a substrate having a sense amplifier region or a word line driver region comprising circuits configured to operate a memory cell array. The substrate further includes a conjunction region adjacent the sense amplifier region or word line driver region and defining a boundary therebetween. A plurality of gate patterns extends on the substrate. The gate patterns include peripheral gate patterns extending in the sense amplifier region or word line driver region, and conjunction gate patterns extending in the conjunction region. Ones of the conjunction gate patterns and ones of the peripheral gate patterns proximate the boundary extend substantially parallel along the boundary between the conjunction region and the sense amplifier region or word line driver region.

In some embodiments, at least one n-type well region may continuously extend from the sense amplifier region or word line driver region into the conjunction region across the boundary therebetween. In some embodiments, at least one p-type well region may continuously extend from the sense amplifier region or word line driver region into the conjunction region across the boundary therebetween, in a direction substantially parallel to the at least one n-type well region.

In some embodiments, the at least one p-type well region and the at least one n-type well region may define different shapes in plan view.

In some embodiments, at least one of the conjunction gate patterns distal from the boundary may extend in a different direction than the peripheral gate patterns.

In some embodiments, the conjunction region may include a first conjunction region adjacent the sense amplifier region that defines a first boundary therebetween, and a second conjunction region adjacent the word line driver region that defines a second boundary therebetween. Ones of the conjunction gate patterns and ones of the peripheral gate patterns proximate the first boundary may extend substantially parallel in a first direction along the first boundary. Ones of the conjunction gate patterns and ones of the peripheral gate patterns proximate the second boundary may extend substantially parallel in a second direction along the second boundary.

According to further example embodiments of the inventive concept, a semiconductor memory device may include a substrate including a cell array region, a sense amp region provided at a side of the cell array region, and a conjunction region provided at a side of the sense amp region, first gate patterns provided in the sense amp region and elongated parallel to a first direction, and second gate patterns provided in the conjunction region. One of the second gate patterns disposed most adjacent to the first gate patterns may be elongated parallel to the first direction.

In example embodiments, all of the second gate patterns may be elongated parallel to the first direction.

In example embodiments, the semiconductor memory device may further include a line-shaped well region provided in the substrate to cross both of the conjunction and sense amp regions.

In example embodiments, the semiconductor memory device may further include first source/drain regions provided at both sides of each of the first and second gate patterns positioned on the well region, and The first source/drain regions may be doped by impurities of a conductivity type different from the well region.

In example embodiments, the semiconductor memory device may further include a first bias line provided in the well region. The first bias line may be elongated along at least one sidewall of the well region and may be spaced apart from the first and second gate patterns, and the first bias line may be doped by impurities of the same conductivity type as the well region.

In example embodiments, the semiconductor memory device may further include second source/drain regions provided at both sides of each of the first and second gate patterns positioned on the substrate outside the well region. The second source/drain regions may be doped by impurities of the same conductivity type as the well region.

In example embodiments, the semiconductor memory device may further include a second bias line provided in the substrate outside the well region. The second bias line may be elongated along at least one sidewall of the well region and may be spaced apart from the first and second gate patterns, and the second bias line may be doped by impurities of a conductivity type different from the well region.

In example embodiments, at least one sidewall of the well region adjacent to the conjunction region has a curved shape, when viewed in plan view.

According to example embodiments of the inventive concept, a semiconductor memory device may include a substrate including a cell array region, a sense amp region provided at a side of the cell array region, a word line driver region provided at other side of the cell array region that does not face the sense amp region, and a conjunction region provided between the sense amp region and the word line driver region, first gate patterns provided in the sense amp region and elongated parallel to a first direction, second gate patterns provided in the word line driver region and elongated parallel to a second direction, and third gate patterns provided in the conjunction region. One of the third gate patterns most adjacent to the first gate patterns may be elongated parallel to the first direction or one of the third gate patterns most adjacent to the second gate patterns may be elongated parallel to the second direction.

In example embodiments, all of the third gate patterns may be elongated parallel to the first or second direction.

In example embodiments, the semiconductor memory device may further include a line-shaped well region provided in the substrate to cross both of the conjunction and sense amp regions or cross both of the conjunction and word line driver regions.

In example embodiments, the semiconductor memory device may further include first source/drain regions provided at both sides of the first or second gate patterns and the third gate patterns positioned on the well region. The first source/drain regions may be doped by impurities of a conductivity type different from the well region.

In example embodiments, the semiconductor memory device may further include a first bias line provided in the well region. The first bias line may be elongated along at least one sidewall of the well region and may be spaced apart from the first or second gate patterns and the third gate patterns, and the first bias line may be doped by impurities of the same conductivity type as the well region.

In example embodiments, the semiconductor memory device may further include second source/drain regions provided at both sides of the first or second gate patterns and the third gate patterns positioned on the substrate outside the well region. The second source/drain regions may be doped by impurities of the same conductivity type as the well region.

In example embodiments, the semiconductor memory device may further include a second bias line provided in the substrate outside the well region. The second bias line may be elongated along at least one sidewall of the well region and may be spaced apart from the first or second gate patterns and the third gate patterns, and the second bias line may be doped by impurities of a conductivity type different from the well region.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a schematic block diagram illustrating a semiconductor memory device according to example embodiments of the inventive concept.

FIG. 2 is a circuit diagram illustrating a portion of a semiconductor memory device, according to example embodiments of the inventive concept.

FIG. 3A is a plan view illustrating a semiconductor memory device, according to example embodiments of the inventive concept.

FIGS. 3B and 3C are sectional views taken along lines A-A′ and B-B′ of FIG. 3A, respectively.

FIGS. 4 through 6 are plan views illustrating semiconductor memory devices according to other example embodiments of the inventive concept.

FIG. 7 is a schematic block diagram illustrating an example of an electronic device including a semiconductor memory device according to example embodiments of the inventive concept.

FIG. 8 is a schematic block diagram illustrating an example of a memory system including a semiconductor memory device according to example embodiments of the inventive concept.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements or layers should be interpreted in a like fashion (e.g., “between” versus “directly between,” “adjacent” versus “directly adjacent,” “on” versus “directly on”). As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

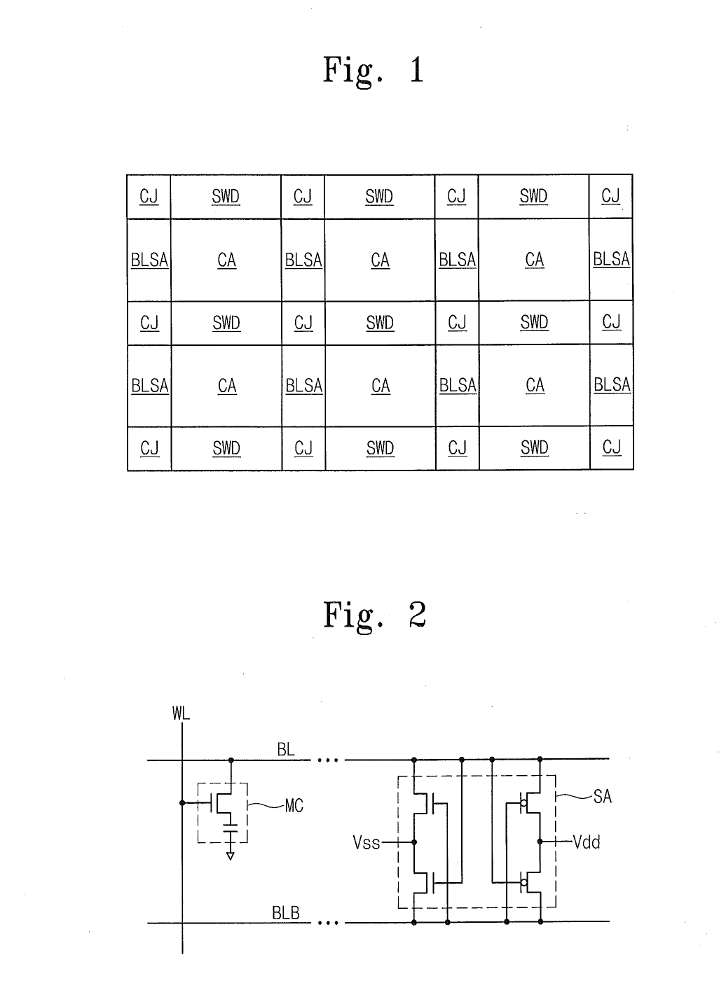

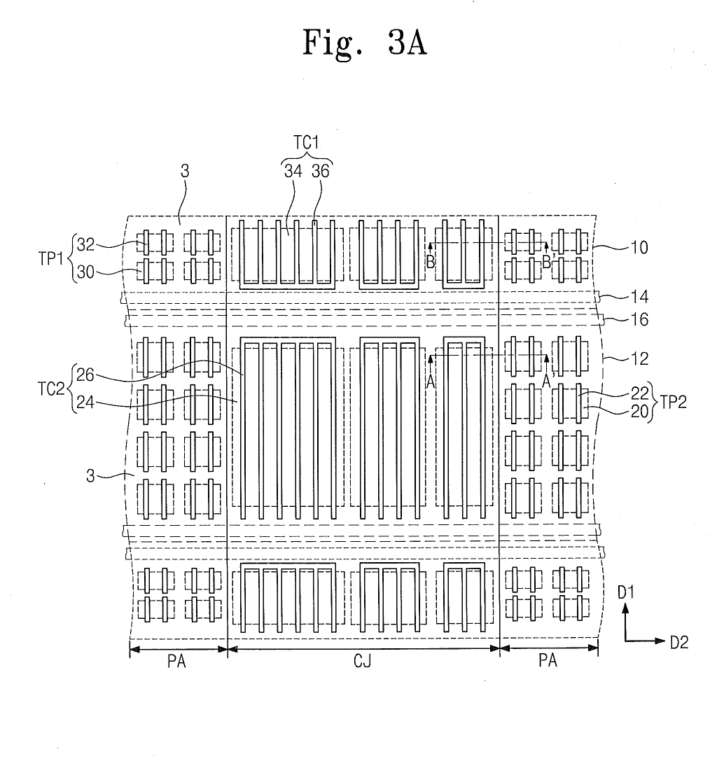

FIG. 1 is a schematic block diagram illustrating a semiconductor memory device according to example embodiments of the inventive concept. FIG. 2 is a circuit diagram illustrating a portion of a semiconductor memory device, according to example embodiments of the inventive concept.

Referring to FIGS. 1 and 2, a semiconductor memory device may include a cell array region CA, a bit line sense amp region BLSA, a sub-word line driver region SWD, and a conjunction region CJ. The bit line sense amp region BLSA may be provided at a side of the cell array region CA, and the sub-word line driver region SWD may be provided at another side of the cell array region CA that does not face the bit line sense amp region BLSA. The conjunction region CJ may be provided at a corner of the cell array region CA to connect the bit line sense amp region BLSA to the sub-word line driver region SWD. In certain embodiments, the semiconductor memory device may be a dynamic random access memory (DRAM) device.

In the cell array region CA, a plurality of word lines WL and a plurality of bit lines BL may be provided to cross each other and thereby constitute or define a plurality of memory cells MC. The cell array region CA may be named as a memory block region. The bit line sense amp region BLSA may be configured to sense and amplify data stored in the memory cell MC and transmit the data to the outside (e.g., to an external device). The bit line sense amp SA may include a plurality of PMOS and NMOS transistors. For example, two PMOS transistors may be connected in series between a bit line BL and a complementary bit line BLB. The two PMOS transistors may have a source region, which may be connected in common to a power voltage Vdd. Further, two NMOS transistors may be connected in series between the bit line BL and the complementary bit line BLB. The two NMOS transistors may have a source region, which may be connected in common to a ground voltage Vss. In the bit line sense amp SA, the bit line BL and the complementary bit line BLB may be initially pre-charged to half of the power voltage Vdd, and a voltage thereof may be elevated or maintained to the pre-charged voltage, depending on a data signal (e.g., voltage) output from the memory cell MC.

In the sub-word line driver region SWD, a sub-word line driver may be provided to control voltages to be applied to the word lines WL. The conjunction region CJ may be provided at a region where the sub-word line driver region SWD and the bit line sense amp region BLSA meet. The conjunction region CJ may include an internal voltage driver (not shown) supplying an internal voltage, which may be used as a voltage source of a bit line sense amp 213, a bit line equalizer (not shown), and/or a circuit for driving the word lines (not shown). In the conjunction region CJ or the sub-word line driver region SWD, a plurality of PMOS transistors and a plurality of NMOS transistors may be disposed to constitute or define a variety of circuits.

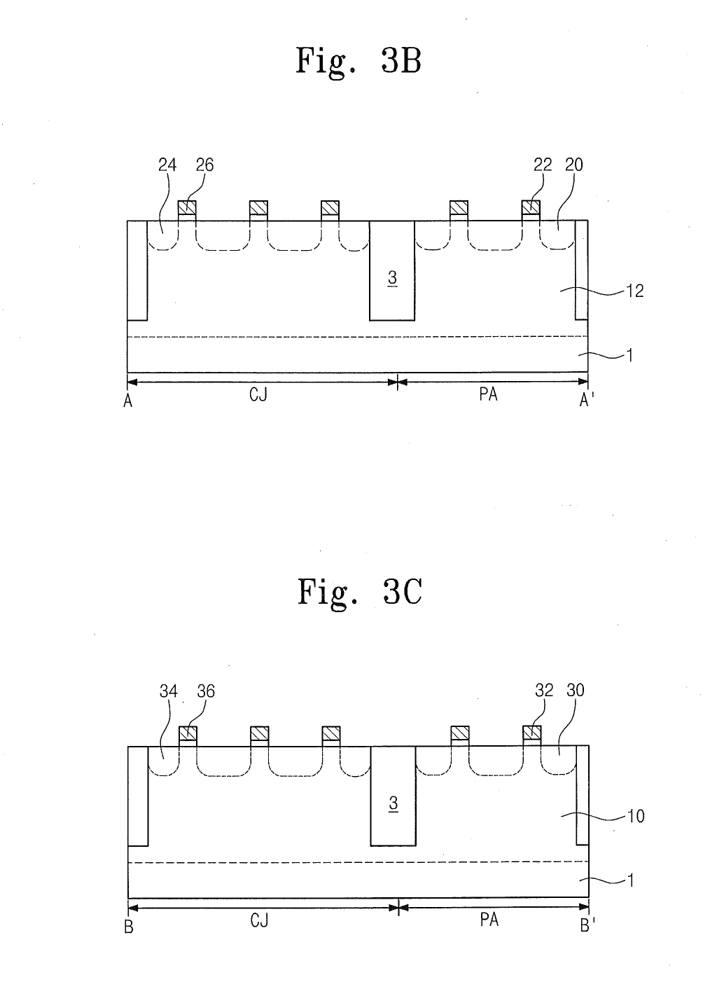

FIG. 3A is a plan view illustrating a semiconductor memory device according to example embodiments of the inventive concept. FIGS. 3B and 3C, respectively, are sectional views taken along lines A-A′ and B-B′ of FIG. 3A.

Referring to FIGS. 3A through 3C, the semiconductor memory device may include a substrate 1. The substrate 1 may be a semiconductor substrate (e.g., a single-crystalline silicon wafer or a silicon-on-insulator (SOI) wafer. The substrate 1 may include the conjunction region CJ and a peripheral region PA. The peripheral region PA may include he bit line sense amp region BLSA or the sub-word line driver region SWD of FIG. 1. For example, the peripheral region PA may refer to the bit line sense amp region BLSA in some embodiments. The substrate 1 may be doped with, for example, P-type impurities.

In the substrate 1, line-shaped or linear first and second wells 10 and 12 may be provided continuously extending parallel to each other to cross both the conjunction region CJ and the peripheral region PA. The first well 10 may be doped by or with impurities of the same conductivity type as the substrate 1, or in certain embodiments, the first well 10 may be omitted. The second well 12 may be doped by or with impurities of a different conductivity type from the substrate 1. For example, the second well 12 may be doped with N-type impurities. A first ground line 14 may be provided in the first well 10 and/or adjacent to a boundary between the first and second wells 10 and 12, and a second ground line 16 may be provided in the second well 12. The first ground line 14 may be doped by impurities of the same conductivity type as the substrate 1 or the first well 10. Further, the first ground line 14 may be doped by impurities of an impurity concentration higher than the substrate 1 or the first well 10. The second ground line 16 may be doped by impurities of the same conductivity type as the second well 12. Further, the second ground line 16 may be doped by impurities of an impurity concentration higher than the second well 12. Each of the first and second ground lines 14 and 16 may have a line-shape structure crossing the conjunction region CJ and the peripheral region PA.

Device isolation layers 3 may be provided on the substrate 1 to define active regions, on which transistors are formed. On the first well 10 of the peripheral region PA, first peripheral gate patterns 32 and first peripheral source/drain regions 30 may be provided to constitute or define first peripheral transistors TP1. Here, the first peripheral source/drain regions 30 may be provided at both opposite sides of each of the first peripheral gate patterns 32. On the second well 12 of the peripheral region PA, second peripheral gate patterns 22 and second peripheral source/drain regions 20 may be provided to constitute or define second peripheral transistors TP2. Here, the second peripheral source/drain regions 20 may be provided at both opposite sides of each of the second peripheral gate patterns 22. On the first well 10 of the conjunction region CJ, first conjunction gate patterns 36 and first conjunction source/drain regions 34 may be provided to constitute or define first conjunction transistors TC1. Here, the first conjunction source/drain regions 34 may be provided at both opposite sides of each of the first conjunction gate patterns 36. On the second well 12 of the conjunction region CJ, second conjunction gate patterns 26 and second conjunction source/drain regions 24 may be provided to constitute or define second conjunction transistors TC2. Here, the second conjunction source/drain regions 24 may be provided at both opposite sides of each of the second conjunction gate patterns 26.

Some (or, in some embodiments, all) of the first and second peripheral gate patterns 32 and 22 may have a shape extending or elongated along a first direction D1. Some (or, in some embodiments, all) of the first and second conjunction gate patterns 36 and 26 may have a shape extending or elongated along the first direction D1.

In the case where longitudinal directions of ones of the conjunction gate patterns 36 and 26 that are disposed most or immediately adjacent to the peripheral region PA are different from each other, ones of the peripheral gate patterns 32 and 22 at the outermost region of the peripheral region PA may have different shapes from others of the peripheral gate patterns 32 and 22 at a center region of the peripheral region PA. In the case where the peripheral region PA is the bit line sense amp region BLSA, this may lead to deterioration in characteristics of the bit line sense amp SA.

However, since the conjunction gate patterns 36 and 26 have a shape extending or otherwise elongated parallel to the peripheral gate patterns 32 and 22, it can be possible to prevent or suppress the patterns from being deformed or distorted by an optical proximity effect, which may occur in a photolithography process for forming the gate patterns 22, 26, 32, and 36. Further, an etching process for forming the gate patterns 22, 26, 32, and 36 can be performed under a spatially-uniform etching condition, which may make it possible to reduce or prevent an electrical bridge between the patterns from occurring. Accordingly, each of the gate patterns 22, 26, 32, and 36 can be formed to have a desired shape, and thus, it may be possible to reduce or prevent deterioration in electrical characteristics of each circuit.

The shapes of the gate patterns 22, 26, 32, and 36 may be variously changed. Further, one or several gate patterns may be disposed to cross one active region. In certain embodiments, a plurality of gate patterns may have end portions connected to each other. The gate patterns 22, 26, 32, and 36 may be formed of a doped polysilicon layer or a metal-containing layer.

The first peripheral transistors TP1 and the first conjunction transistors TC1 may be, for example, NMOS transistors. The first peripheral source/drain regions 30 and the first conjunction source/drain regions 34 may be doped with, for example, n-type impurities. The first peripheral gate patterns 32 and the first conjunction gate patterns 36 may be formed of an n-type doped polysilicon layer or a metal-containing layer, whose work-function is substantially equivalent to that of the n-type doped polysilicon layer.

The second peripheral transistors TP2 and the second conjunction transistors TC2 may be, for example, PMOS transistors. The second peripheral source/drain regions 20 and the second conjunction source/drain regions 24 may be doped with, for example, p-type impurities. The second peripheral gate patterns 22 and the second conjunction gate patterns 26 may be formed of a p-type doped polysilicon layer or a metal-containing layer, whose work-function is substantially equivalent to that of the p-type doped polysilicon layer.

Since the well regions 10 and 12 have a line-shape structure or extend linearly crossing the conjunction region CJ and the peripheral region PA, and the corresponding transistors TP1, TP2, TC1, and TC2 are formed thereon, respectively, it may be possible to reduce or suppress deterioration in uniformity of the device, which may be caused by a well proximity effect. Accordingly, it may be possible to lower a discrepancy of a sub-bias in each region.

Since the ground lines 14 and 16 have a linear or line-shape structure crossing the conjunction region CJ and the peripheral region PA, it may be possible to enhance the sub-bias in each region.

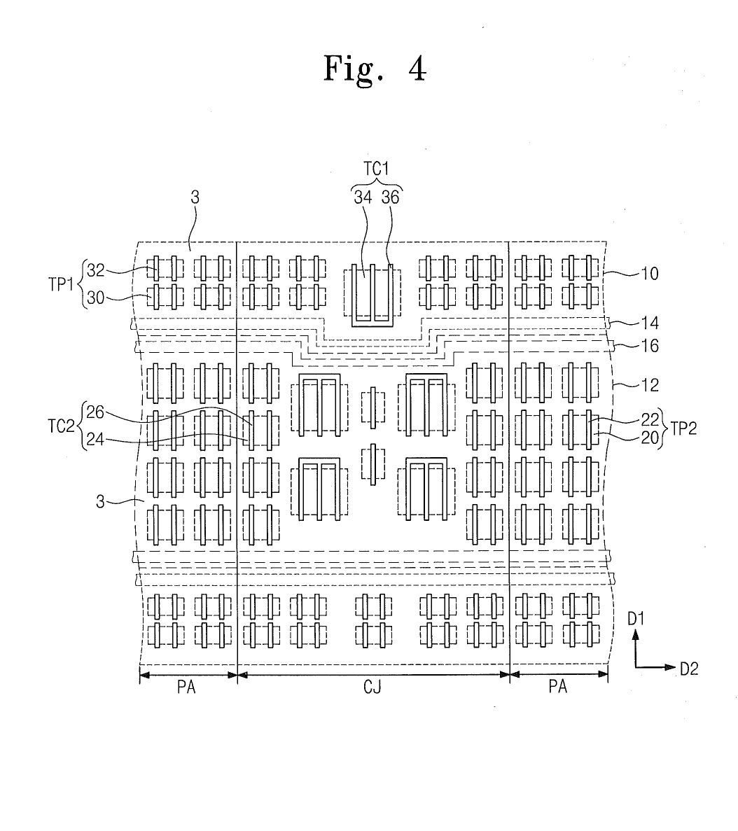

FIGS. 4 through 6 are plan views illustrating semiconductor memory devices according to other example embodiments of the inventive concept.

Referring to FIG. 4, according to the present embodiments of the inventive concept, a semiconductor memory device may include the wells 10 and 12, whose shapes are different from those described with reference to FIG. 3A. For example, in the conjunction region CJ, the second well 12 may be formed to have a concave shape, when viewed in plan view. Accordingly, the first well 10 may include a region protruding toward the second well 12. As the result of the change in shapes of the wells 10 and 12, shapes of the ground lines 14 and 16 may be changed in a similar manner. Here, the number or an area of the first conjunction transistors TC1 provided in the first well 10 may be increased. Shapes of the conjunction gate patterns 36 and 26 may be changed, compared with those of FIG. 3A. In some embodiments, in contrast to the structure of FIG. 4, the second well 12 may be formed to have a convex shape, when viewed in plan view. For example, the second well 12 may include a region protruding toward the first well 10, and thus, shapes of the ground lines 14 and 16 may be changed. The semiconductor memory device may otherwise be configured to be substantially similar to FIG. 3A.

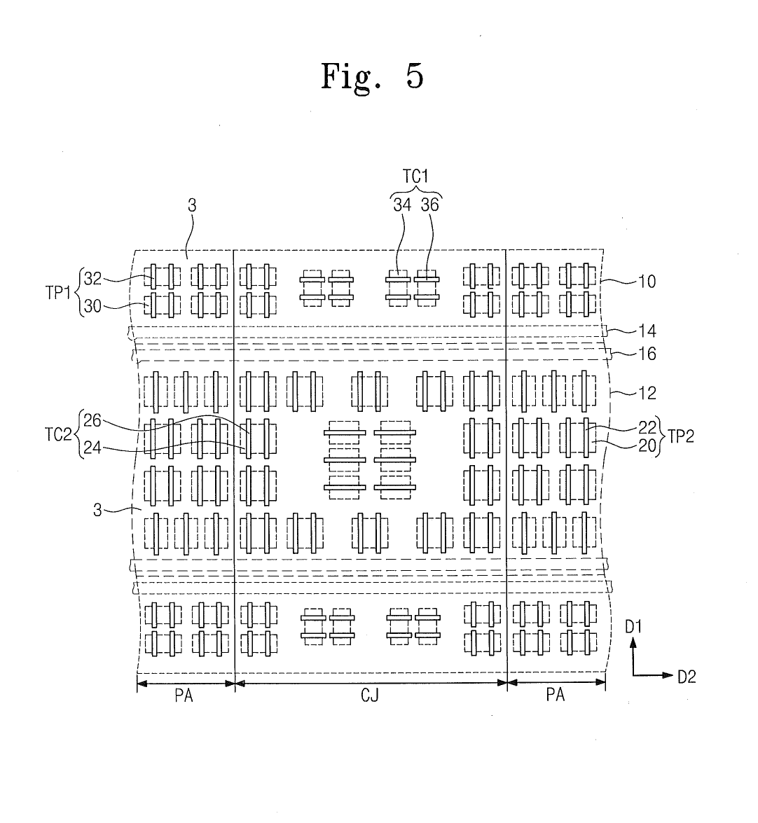

Referring to FIG. 5, in a semiconductor memory device, at least one of the conjunction gate patterns 36 and 26 may be formed to have a different longitudinal direction (that is, to extend in a different direction) from the others. For example, some of the conjunction gate patterns 36 and 26 at a central region of the conjunction region CJ may extend or otherwise be elongated along a second direction D2, which is not parallel to the peripheral gate patterns 32 and 22. However, the conjunction gate patterns 36 and 26 disposed most or immediately adjacent to the peripheral region PA (that is, along a boundary between the conjunction region CJ and the peripheral region PA) may extend or otherwise be elongated along the first direction D1, which is parallel to the peripheral gate patterns 32 and 22. In the present embodiments, it is possible to dispose the conjunction gate patterns 36 and 26 with increased freedom. The semiconductor memory device may otherwise be configured to be substantially similar to FIG. 3A.

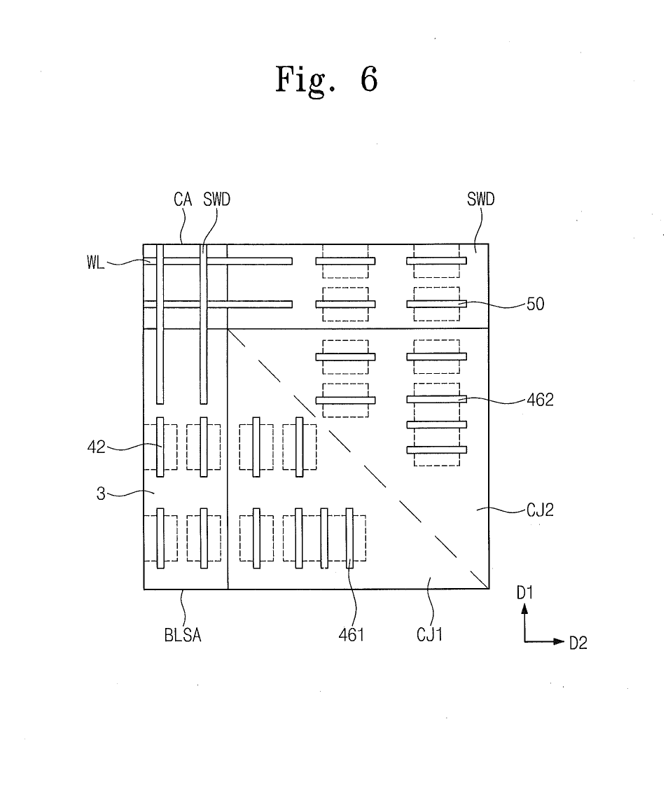

Referring to FIG. 6, according to some embodiments of the inventive concept, a semiconductor memory device may include the cell array region CA, the bit line sense amp region BLSA, the sub-word line driver region SWD, and conjunction region CJ1 and CJ2. In the cell array region CA, the bit lines BL and the word lines WL may be provided to cross each other. In the bit line sense amp region BLSA, sense amp gate patterns 42 may be provided parallel to the bit line BL or the first direction D1. In the sub-word line driver region SWD, driver gate patterns 50 may be provided parallel to the word line WL or the second direction D2. The conjunction region CJ1 and CJ2 may include a first conjunction region CJ1 adjacent to the bit line sense amp region BLSA and a second conjunction region CJ2 adjacent to the sub-word line driver region SWD. In the first conjunction region CJ1, first conjunction gate patterns 461 may be provided parallel to the sense amp gate patterns 42 or the first direction D1. In the second conjunction region CJ2, second conjunction gate patterns 462 may be provided parallel to the driver gate patterns 50 or the second direction D2. Accordingly, it may be possible to reduce or prevent line widths of the gate patterns 42 and 50 from being changed at an edge of the regions BLSA and SWD, and thereby to reduce or prevent each circuit from being deteriorated. Except for this difference, the semiconductor memory device may be configured to be substantially the same as those described with reference to FIGS. 1 through 3A.

In FIG. 6, the first and second conjunction gate patterns 461 and 462 are illustrated to be parallel to the sense amp gate patterns 42 and the driver gate patterns 50, which are adjacent thereto, respectively, and thereby have different longitudinal directions from each other, but in certain embodiments, some or all of the first and second conjunction gate patterns 461 and 462 may be provided to extend along the same direction (for example, parallel to the sense amp gate patterns 42 or the driver gate patterns 50).

The semiconductor memory devices disclosed above may be encapsulated using various and/or diverse packaging techniques. For example, the semiconductor memory devices according to the aforementioned embodiments may be encapsulated using any of a package on package (POP) technique, a ball grid arrays (BGAs) technique, a chip scale packages (CSPs) technique, a plastic leaded chip carrier (PLCC) technique, a plastic dual in-line package (PDIP) technique, a die in waffle pack technique, a die in wafer form technique, a chip on board (COB) technique, a ceramic dual in-line package (CERDIP) technique, a plastic quad flat package (PQFP) technique, a small outline package (SOIC) technique, a shrink small outline package (SSOP) technique, a thin small outline package (TSOP) technique, a thin quad flat package (TQFP) technique, a system in package (SIP) technique, a multi-chip package (MCP) technique, a wafer-level fabricated package (WFP) technique and a wafer-level processed stack package (WSP) technique.

The package in which the semiconductor memory device according to one of the above embodiments is mounted may further include at least one semiconductor device (e.g., a controller and/or a logic device) that controls the semiconductor memory device.

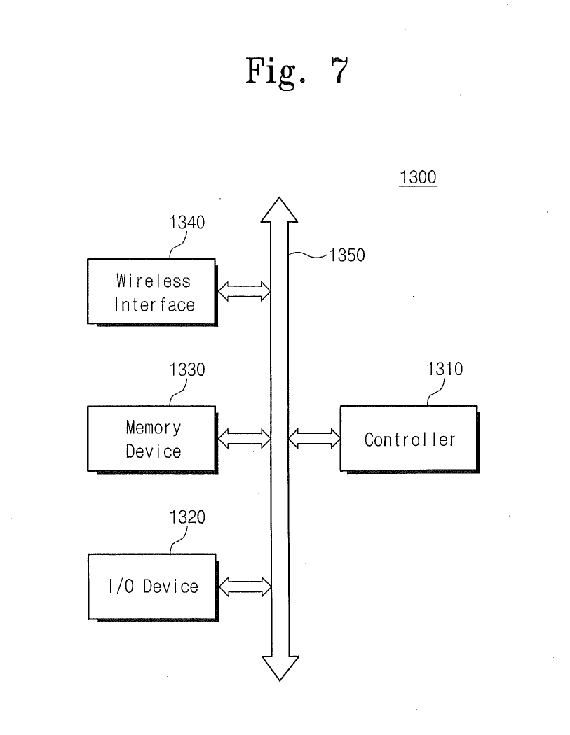

FIG. 7 is a schematic block diagram illustrating an example of electronic devices including a semiconductor memory device according to example embodiments of the inventive concept.

Referring to FIG. 7, an electronic device 1300 including a semiconductor device according to example embodiments of the inventive concept may be used in one of a personal digital assistant (PDA), a laptop computer, a mobile computer, a web tablet, a wireless phone, a cell phone, a digital music player, a wire or wireless electronic device, or an electronic device including at least two ones thereof. The electronic device 1300 may include a controller 1310, an input/output device 1320 such as a keypad, a keyboard, and/or a display, a memory 1330, and a wireless interface 1340 that are combined or communicatively coupled with each other through a bus 1350. The controller 1310 may include, for example, a microprocessor, a digital signal process, a microcontroller, and/or the like. The memory 1330 may be configured to store a command code to be used by the controller 1310 or a user data. The memory 1330 may include a semiconductor device according to example embodiments of the inventive concept. The electronic device 1300 may use a wireless interface 1340 configured to transmit data to or receive data from a wireless communication network using a RF signal. The wireless interface 1340 may include, for example, an antenna, a wireless transceiver, and so on. The electronic system 1300 may be used in a communication interface protocol of a communication system such as CDMA, GSM, NADC, E-TDMA, WCDMA, CDMA2000, Wi-Fi, Muni Wi-Fi, Bluetooth, DECT, Wireless USB, Flash-OFDM, IEEE 802.20, GPRS, iBurst, WiBro, WiMAX, WiMAX-Advanced, UMTS-TDD, HSPA, EVDO, LTE-Advanced, MMDS, and so forth.

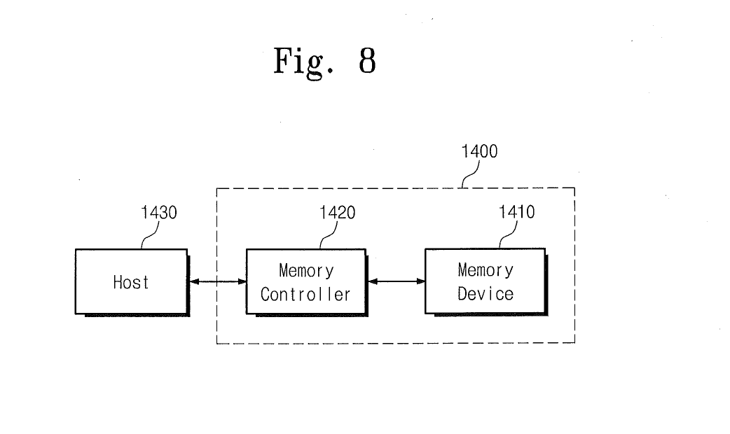

FIG. 8 is a schematic block diagram illustrating an example of a memory system including a semiconductor memory device according to example embodiments of the inventive concept.

Referring to FIG. 8, a semiconductor device according to example embodiments of the inventive concept may be used to realize a memory system 1400. The memory system 1400 may include a memory device 1410 for storing data and a memory controller 1420. The memory controller 1420 controls the memory device 1410 so as to read data stored in the memory device 1410 or to write data into the memory device 1410 in response to a read/write request from a host 1430. The memory controller 1420 may include an address mapping table for mapping an address provided from the host 1430 (e.g., a mobile device or a computer system) into a physical address of the memory device 1410. The memory device 1410 may be a semiconductor device according to example embodiments of the inventive concept.

According to example embodiments of the inventive concept, the semiconductor memory device may include a conjunction region having gate patterns that extend substantially parallel to other gate patterns in a sense amp region adjacent thereto. Accordingly, when the gate patterns in the sense amp region are formed, the gate patterns can be prevented from having undesired line widths. Thus, deterioration in electrical characteristics of a sense amplifier circuit may be reduced or prevented.

While example embodiments of the inventive concepts have been particularly shown and described, it will be understood by one of ordinary skill in the art that variations in form and detail may be made therein without departing from the spirit and scope of the attached claims.

What is claimed is:

1. A semiconductor memory device, comprising:
a substrate including a cell array region, a sense amp region provided at a side of the cell array region, and a conjunction region provided at a side of the sense amp region;
first gate patterns in the sense amp region and elongated parallel to a first direction; and
second gate patterns in the conjunction region,
wherein one of the second gate patterns disposed immediately adjacent to the first gate patterns is elongated parallel to the first direction.

2. The semiconductor memory device of claim 1, wherein a plurality of the second gate patterns are elongated parallel to the first direction.

3. The semiconductor memory device of claim 1, further comprising:
a line-shaped well region in the substrate extending across both of the conjunction and sense amp regions.

4. The semiconductor memory device of claim 3, further comprising:
first source/drain regions provided at opposite sides of each of the first and second gate patterns positioned on the well region,
wherein the first source/drain regions are doped with impurities of a conductivity type different from the well region.

5. The semiconductor memory device of claim 3, further comprising:
a first bias line in the well region,
wherein the first bias line is elongated along at least one sidewall of the well region and is spaced apart from the first and second gate patterns, and
wherein the first bias line is doped with impurities of a same conductivity type as the well region.

6. The semiconductor memory device of claim 3, further comprising:
second source/drain regions provided at opposite sides of each of the first and second gate patterns positioned on the substrate outside the well region,
wherein the second source/drain regions are doped with impurities of a same conductivity type as the well region.

7. The semiconductor memory device of claim 6, further comprising:
a second bias line in the substrate outside the well region,
wherein the second bias line is elongated along at least one sidewall of the well region and is spaced apart from the first and second gate patterns, and
wherein the second bias line is doped with impurities of a conductivity type different from the well region.

8. The semiconductor memory device of claim 3, wherein at least one sidewall of the well region adjacent to the conjunction region has a curved shape, when viewed in plan view.

9. A semiconductor memory device, comprising:
a substrate including a cell array region, a sense amp region at a side of the cell array region, a word line driver region at an other side of the cell array region that does not face the sense amp region, and a conjunction region between the sense amp region and the word line driver region;
first gate patterns in the sense amp region and elongated parallel to a first direction;
second gate patterns in the word line driver region and elongated parallel to a second direction; and
third gate patterns in the conjunction region,
wherein one of the third gate patterns adjacent a boundary between the conjunction region and the sense amp region is elongated parallel to the first direction, or wherein one of the third gate patterns adjacent a boundary between the conjunction region and the word line driver region is elongated parallel to the second direction.

10. The semiconductor memory device of claim 9, wherein a plurality of the third gate patterns are elongated parallel to the first or second direction.

11. The semiconductor memory device of claim 9, further comprising:
a line-shaped well region in the substrate extending across both of the conjunction and sense amp regions or across both of the conjunction and word line driver regions.

12. The semiconductor memory device of claim 11, further comprising:
first source/drain regions at opposite sides of the first or second gate patterns and the third gate patterns positioned on the well region,
wherein the first source/drain regions are doped with impurities of a conductivity type different from the well region.

13. The semiconductor memory device of claim 12, further comprising:
a first bias line in the well region,
wherein the first bias line is elongated along at least one sidewall of the well region and is spaced apart from the first or second gate patterns and the third gate patterns, and
wherein the first bias line is doped with impurities of a same conductivity type as the well region.

14. The semiconductor memory device of claim 11, further comprising:
second source/drain regions at opposite sides of the first or second gate patterns and the third gate patterns positioned on the substrate outside the well region,
wherein the second source/drain regions are doped with impurities of a same conductivity type as the well region.

15. The semiconductor memory device of claim 14, further comprising:
a second bias line in the substrate outside the well region,
wherein the second bias line is elongated along at least one sidewall of the well region and is spaced apart from the first or second gate patterns and the third gate patterns, and
wherein the second bias line is doped with impurities of a conductivity type different from the well region.

16. An integrated circuit memory device, comprising:
a substrate including a sense amplifier region or a word line driver region comprising circuits configured to operate a memory cell, and a conjunction region adjacent the sense amplifier region or word line driver region and defining a boundary therebetween; and
a plurality of gate patterns on the substrate, the gate patterns comprising conjunction gate patterns extending in the conjunction region and peripheral gate patterns extending in the sense amplifier region or word line driver region,
wherein ones of the conjunction gate patterns and ones of the peripheral gate patterns proximate the boundary extend substantially parallel therealong.

17. The device of claim 16, further comprising:
at least one n-type well region continuously extending from the sense amplifier region or word line driver region into the conjunction region across the boundary therebetween; and
at least one p-type well region continuously extending from the sense amplifier region or word line driver region into the conjunction region across the boundary therebetween, in a direction substantially parallel to the at least one n-type well region.

18. The device of claim 17, wherein the at least one p-type well region and the at least one n-type well region define different shapes in plan view.

19. The device of claim 17, wherein the conjunction region is between the sense amplifier region and the word line driver region adjacent a corner of the memory cell, and wherein at least one of the conjunction gate patterns distal from the boundary extends in a different direction than the peripheral gate patterns.

20. The device of claim 19, wherein the conjunction region comprises a first conjunction region adjacent the sense amplifier region and defining a first boundary therebetween, and a second conjunction region adjacent the word line driver region and defining a second boundary therebetween,
wherein ones of the conjunction gate patterns and ones of the peripheral gate patterns proximate the first boundary extend substantially parallel in a first direction therealong, and
wherein ones of the conjunction gate patterns and ones of the peripheral gate patterns proximate the second boundary extend substantially parallel in a second direction therealong.
